(19) United States
(12) Patent Application Publication
(10) Pub. No.: US 2009/0134898 A1
(43) Pub. Date: May 28, 2009

(54) Coaxial Spring Probe Grounding Method

(76) Inventors: Richard D. Carlsen, Mesa, AZ (US); Shawn Van Haren, Gilbert, AZ (US); David Moore, Portland, OR (US)

Correspondence Address: CARSTENS & CAHOON, LLP, P O BOX 802334, DALLAS, TX, 75380, US

(21) Appl. No.: 12/145,353

(22) Filed: Jun. 24, 2008

Related U.S. Application Data
(60) Provisional application No. 60/990,268, filed on Nov. 26, 2007.

(51) Int. Cl. G01R 1/073

(52) U.S. Cl. 324/761

(57) ABSTRACT

The present invention provides a spring probe array for use in a semiconductor test fixture wherein the spring probes provide electrical continuity between a device under test and a test system. The array includes a spring probe retaining device with sockets for supporting spring probes. Fixed within the retaining device are a plurality of signal spring probes and a plurality of ground spring probes. A grounding board is fixed internal and captive to the spring probe retaining device and provides a common grounding connection between coaxial spring probes and adjacent non-coaxial spring probes in the spring probe retaining device.

### CROSS-REFERENCE TO RELATED APPLICATION

This application claims the benefit of and priority to U.S. Provisional Patent Application No. 60/990,268 filed Nov. 26, 2007 the technical disclosures of which are hereby incorporated herein by reference.

### TECHNICAL FIELD

The present invention relates generally to spring probe block assemblies used in automated test equipment, and more specifically to coaxial spring probe grounding method utilizing a proprietary grounding board internal to the spring prove retaining device.

### BACKGROUND OF THE INVENTION

The semiconductor test industry uses an interface to transfer signals from a device under test (DUT) to a test system. This device typically contains thousands of transistors that are to be tested. The interface between the DUT and the test system comprises a spring probe array that affords a temporary connection between the DUT and the system.

FIG. 1 shows a traditional spring probe array tower with its arrays of spring probes projecting upwards in accordance with the prior art. A typical test setup utilizes a spring probe array with a multitude of spring probes for contacting the DUT. Test signals flow between the test setup and the DUT across the probe connections. Quite often, this device testing requires that the signal impedance be tightly controlled between the DUT and the test system. This is necessary when dealing with high circuit frequencies or when power transfer between the devices must be maximized. Improper impedance can cause reflected signals which interfere with circuit measurements.

The spring probe array includes signal probes and ground probes. FIG. 2 shows the ground and signal spring probe placement of the traditional spring probe array in accordance with the prior art. Ground probes are spaced appropriately among the signal probes to influence the signal probe impedance. Traditional probe arrays require such a high number of ground probes that a physical limitation is imposed on the possible number of signal probes. This further imposes a limitation on the number of transistors that can be tested.

When a DUT is placed in a test fixture, the spring probe array tower is held in contact with the circuit connections. The test fixture must compress the spring probe array tower sufficiently to establish adequate circuit contact. Test systems with interface compression force limits periodically suffer from lack of sufficient signal spring probes through the interface due to the large number of ground spring probes used to control the impedance of the signals. This is because each spring probe requires some amount of force to compress the probe against the DUT to obtain sufficient contact. The overall test system compression force required is directly proportional to the number of spring probes. In a typical spring probe array, the forces required to adequately compress the multitude of spring probes contacting the DUT can often exceed the test fixture compression force limits.

Accordingly, a need exists for a signal spring probe array that allows a reduced number of ground spring probes to control the impedance of the same or an increased number of signal spring probes. Further, a need exists for a spring probe array that provides a greater number of signal spring probes without exceeding tester compression force limits. There is also a need to provide a method for grounding the shields of the coaxial spring probes to a common ground when spring probes are retained within a non-conductive material.

### SUMMARY OF THE INVENTION

The present invention provides a spring probe array for use in a semiconductor test fixture wherein the spring probes provide electrical continuity between a device under test and a test system. The array includes a spring probe retaining device with sockets for supporting spring probes. Fixed within the retaining device are a plurality of signal spring probes and a plurality of ground spring probes. A grounding board is fixed internal and captive to the spring probe retaining device and provides a common grounding connection between coaxial spring probes and adjacent non-coaxial spring probes in the spring probe retaining device. This method of spring probe grounding provides a high integrity common (or isolated) ground connection to the spring probe socket, or outer shielding jacket of a coaxial spring probe

### BRIEF DESCRIPTION OF THE DRAWINGS

The novel features believed characteristic of the invention are set forth in the appended claims. The invention itself, however, as well as a preferred mode of use, further objects and advantages thereof, will best be understood by reference to the following detailed description of an illustrative embodiment when read in conjunction with the accompanying drawings, wherein:

FIG. 1 shows a traditional spring probe array tower with its arrays of spring probes projecting upwards in accordance with the prior art;

FIG. 2 shows the ground and signal spring probe placement of the traditional spring probe array in accordance with the prior art;

FIG. 3 shows a section of a spring probe array in accordance with a preferred embodiment of the present invention;

FIG. 4 is a top plan view of a spring probe array tower housing in accordance with the present invention;

FIG. 5A is a side, cross-sectional view of the spring probe tower array in accordance with the present invention; and

FIG. 5B is a detailed view of the spring probe array cross section.

### DETAILED DESCRIPTION OF THE DRAWINGS

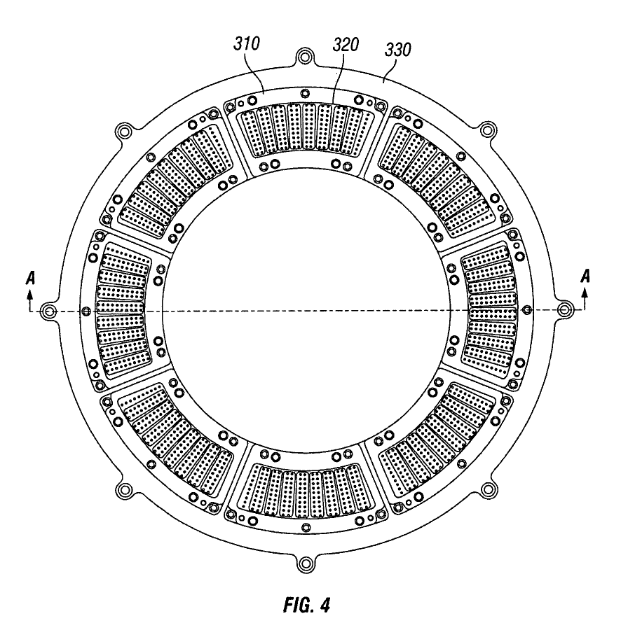

FIG. 3 shows a section of a spring probe array in accordance with a preferred embodiment of the present invention. The spring probe array comprises both coaxial spring probes (301) and non-coaxial spring probes (302). These are grouped together and held by a spring probe retainer block (310). The coaxial spring probes (301) are the signal probes, and the non-coaxial spring probes (302) are either grounded spring probes that provide a path to common ground or non-grounded spring probes. The spring probes utilized are of the industry standard variety well known in the art.

The coaxial signal spring probes (301) in this embodiment are aligned in a coplanar parallel row-column configuration in the array. The coaxial signal probes (301) alternate with the non-coaxial ground probes (302) within each column. The sequence of signal probe and ground probe is alternated between columns, as shown in FIG. 3.

To control the impedance of the signal probes (301) a grounding board (320) that provides common grounding is placed internal and captive to the spring probe retainer (310). In a preferred embodiment, the grounding board (320) is a two-layer printed circuit board typically constructed from industry standard Flame Retardant 4 (FR-4) material. The design of the grounding board (320) is specific to the needs of the associated spring probe retaining block. The grounding board (320) is designed to provide a common ground between coaxial spring probes and adjacent non-coaxial spring probes only within the two adjacent radial rows as shown. This method of spring probe grounding provides a high integrity, common (or isolated) ground connection to the spring probe socket, or outer shielding jacket of a coaxial spring probe.

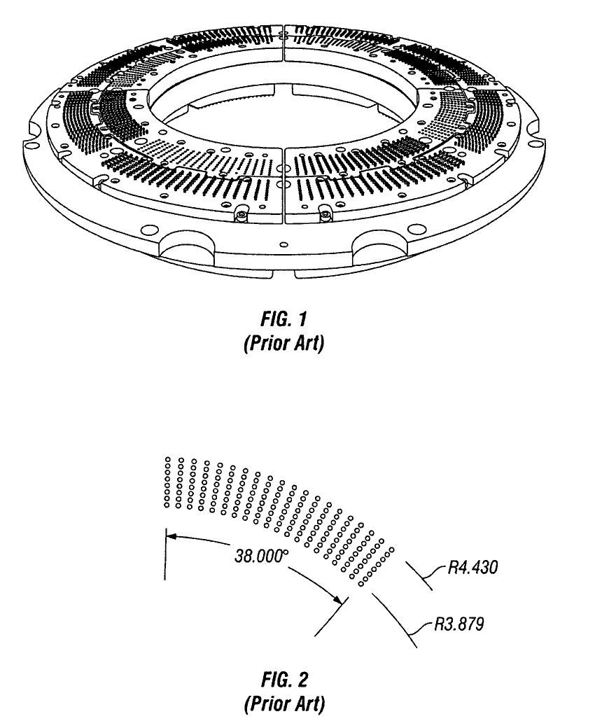

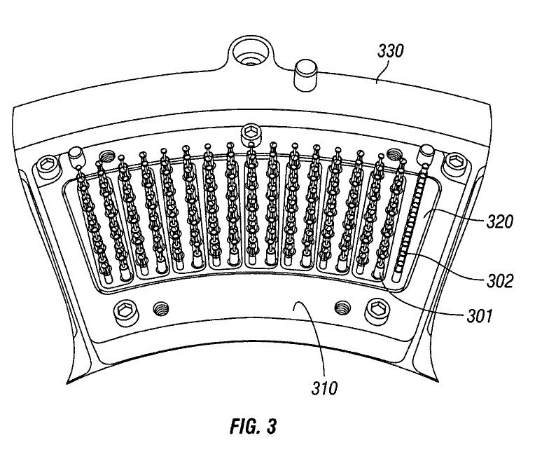

As shown in FIGS. 1 and 2, the prior art method for controlling the impedance of the signal spring probes comprises placing a row of ground probes between each row of signal spring probes. However, this even row-column spacing of the signal and ground probes requires a significant amount of surface area, resulting in large probe array towers. Signal spring probe impedance is affected by the distance between a signal probe and a ground probe. Depending on its location in the array, one ground probe can influence the impedance of two to four signal probes. The diameter of the probes and the dielectric constant of the material in which probes are supported determine the signal probe impedance. Accordingly, using materials with a different dielectric constant or using probes with different diameters may require different spacing between the ground and signal probes.

The grounding board (320) of the present invention reduces the need for ground connections at or near the end of the spring probes on the interfacing printed circuit board, thereby saving critical design space. By using the ground board (320) within the spring probe retainer (310) to replace non-coaxial spring probe retaining devices, the present invention allows coaxial spring probes to be used to improve signal integrity, even when the interfacing circuit board is not designed to accommodate coaxial spring probes.

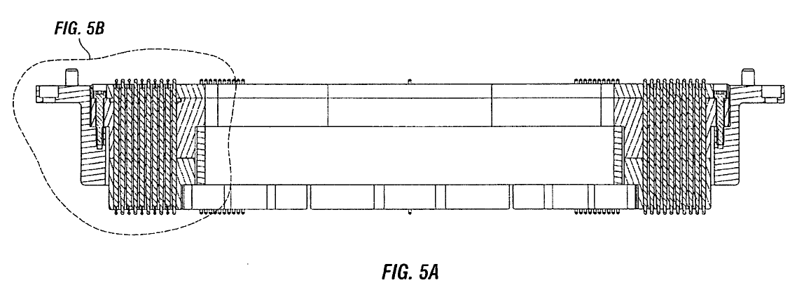

The spring probe array and grounding board (320) is mounted in a retainer block (310) which is mounted in a spring probe array tower housing (330) for use in a test fixture. The tower housing holds multiple spring probe retainer blocks, as shown in FIG. 4.

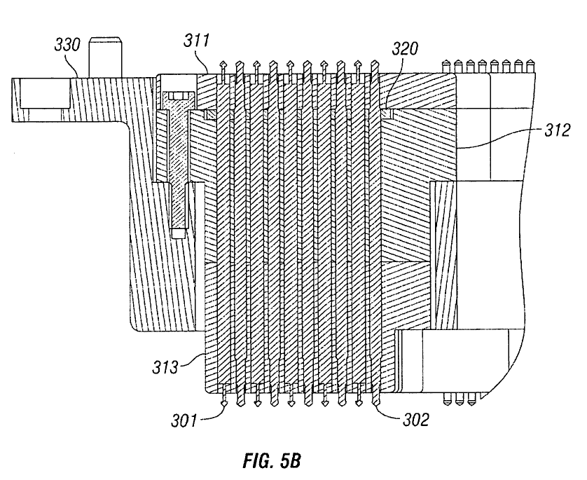

FIG. 5A is a side, cross-sectional view of the spring probe tower array in accordance with the present invention. This cross-sectional view shows the details of the coaxial and non-coaxial spring probes held within the retaining device. FIG. 5B is a more detailed view of the spring probe array cross section.

The spring probe array retainer block serves as a spring probe support device and is typically a glass-filled or thermosetting resin material having determinate dielectric properties. The dielectric coefficient of this material is used in the signal spring impedance calculations. Use of different materials having differing coefficients can influence the overall size of the spring probe array.

As shown in the more detailed view in FIG. 5B, the retaining block is divided into three sections, a top retainer (311), a middle block (312), and a bottom retainer (313). The grounding board (320) is held between the top retainer (311) and the middle block (312). In an alternate embodiment (not shown), the grounding board is mounted between the bottom retainer and middle block. Furthermore, the spring probe module might designed with different block layers than those depicted in FIGS. 5A and 5B, allowing the grounding board to be place between different blocks, depending on the design of the spring probe module.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated. It will be understood by one of ordinary skill in the art that numerous variations will be possible to the disclosed embodiments without going outside the scope of the invention as disclosed in the claims.

I claim:

1. A spring probe array for use in a semiconductor test fixture wherein the spring probes provide electrical continuity between a device under test and a test system, the array comprising:
(a) a spring probe retaining device with sockets for supporting spring probes;
(b) a plurality of signal spring probes, wherein the signal probes are fixed within the spring probe retaining device;
(c) a plurality of ground spring probes, wherein the ground probes are fixed within the spring probe retaining device; and
(d) a grounding board internal and captive to the spring probe retaining device, wherein the grounding board provides a grounding connection to the spring probes in the spring probe retaining device.

2. The spring probe array according to claim 1, wherein the grounding board provides a common grounding connection between signal spring probes and adjacent ground spring probes in the spring probe retaining device.

3. The spring probe array according to claim 1, wherein the grounding board provides a grounding connection to the sockets in the spring probe retaining device.

4. The spring probe array according to claim 1, wherein the grounding board provides a grounding connection to outer shielding jackets of the signal spring probes.

5. The spring probe array according to claim 1, wherein the signal spring probes are arranged in a parallel row-column configuration.

6. The spring probe array according to claim 5, wherein the signal spring probes are arranged in an alternating fashion with the ground probes within each column.

7. The spring probe array according to claim 1, wherein the grounding board comprises a two-layer printed circuit board.

8. The spring probe array according to claim 1, wherein the spring probe array is mounted in a retainer block that in turn is mounted in a spring probe array tower housing for use in a test fixture.

9. The spring probe array according to claim 8, wherein said retainer block is divided into three sections:
a top retainer;
a middle block; and
a bottom retainer;
wherein the grounding board is held between the top retainer and the middle block.

10. The spring probe array according to claim 8, wherein said retainer block is divided into three sections:
a top retainer;
a middle block; and
a bottom retainer;
wherein the grounding board is held between the middle block and bottom retainer.
